(19) United States
(12) Patent Application Publication
(10) Pub. No.: US 2026/0214851 A1
(43) Pub. Date: Jul. 23, 2026

(54) SYSTEMS AND METHODS FOR EVAPORATIVE COOLING

(71) Applicant: Toyota Motor Engineering & Manufacturing North America, Inc., Plano, TX (US)

(72) Inventor: Shailesh N. Joshi, Ann Arbor, MI (US)

(73) Assignee: Toyota Motor Engineering & Manufacturing North America, Inc., Plano, TX (US)

(21) Appl. No.: 19/033,014

(22) Filed: Jan. 21, 2025

(51) Int. Cl. H05K 7/20

(52) U.S. Cl. CPC H05K 7/20327

(57) ABSTRACT

This application is related to cooling assemblies that include a plurality of droplet-forming zones on a conductive evaporative substrate, a manifold comprising a plurality of droplet outlets fluidly coupled to a liquid inlet port for receiving cooling liquid, a chamber positioned between the conductive evaporative substrate and the manifold and operable to transport vapor from the plurality of droplet-forming zones to a vapor outlet port, and a voltage supply configured to provide an actuation voltage between the conductive evaporative substrate and the manifold. The actuation voltage is operable to adjust a surface wettability of each droplet-forming zone of the plurality of droplet-forming zones and a contact angle of a droplet of the cooling liquid in each droplet-forming zone of the plurality of droplet-forming zones.

The present disclosure is directed to cooling systems, more particularly, evaporative cooling systems.

### BACKGROUND

Power electronic devices, such as insulated-gated bipolar transistors (IGBTs) and metal-oxide-semiconductor field-effect transistors (MOSFETs), generate significant heat fluxes that must be removed to ensure that they operate below their maximum operating temperatures. Currently, heat sinks and liquid-based coolers are frequently used cooling devices for electronic devices. One example is a droplet-based evaporative cooler, in which droplets of liquid are formed on an evaporation surface and subsequently evaporated by a heat-generating device, such as an electronic device.

### BRIEF SUMMARY

Embodiments disclosed herein provide cooling assemblies and methods to control the formation of droplets and their boiling behaviors, addressing the need for tunable droplet-based evaporative coolers that meet the individual heat flux removal requirements of a heat-generating device. Particularly, the example cooling assemblies disclosed herein include a plurality of droplet-forming zones that are capable of facilitating surface rewetting to minimize film boiling and therefore achieve delayed critical heat flux (CHF) and improved cooling efficiency.

In one embodiment, a cooling assembly includes a plurality of droplet-forming zones on a conductive evaporative substrate, a manifold comprising a plurality of droplet outlets fluidly coupled to a liquid inlet port for receiving cooling liquid, a vapor chamber positioned between the conductive evaporative substrate and the manifold and operable to transport vapor from the plurality of droplet-forming zones to a vapor outlet port and a voltage supply configured to provide an actuation voltage between the conductive evaporative substrate and the manifold. The actuation voltage is operable to adjust a surface wettability of each droplet-forming zone of the plurality of droplet-forming zones and a contact angle of a droplet of the cooling liquid in each droplet-forming zone of the plurality of droplet-forming zones.

In one embodiment, a method of cooling a heat generating component includes providing an actuation voltage and cooling liquid to a cooling assembly configured to receive heat flux from the heat generating component, receiving the cooling liquid from the plurality of droplet outlets to form a droplet on each droplet-forming zone of the plurality of droplet-forming zones, receiving heat flux from the heat generating component, and transporting vapor from the plurality of droplet-forming zones to the vapor outlet port and thereby removing heat flux from the heat generating component. The cooling assembly includes a plurality of droplet-forming zones on a conductive evaporative substrate, a manifold comprising a plurality of droplet outlets fluidly coupled to a liquid inlet port for receiving the cooling liquid, a voltage supply configured to provide the actuation voltage between the conductive evaporative substrate and the manifold, and a vapor chamber positioned between the conductive evaporative substrate and the manifold and operable to transport vapor from the plurality of droplet-forming zones to a vapor outlet port. The actuation voltage is operable to adjust a surface wettability of each droplet-forming zone of the plurality of droplet-forming zones and a contact angle of a droplet of the cooling liquid in each droplet-forming zone of the plurality of droplet-forming zones.

Additional features and advantages will be set forth in the detailed description that follows, and in part will be readily apparent to those skilled in the art from that description or recognized by practicing the embodiments described herein, including the detailed description that follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1 illustrates a perspective view of an example cooling assembly according to one or more embodiments described and illustrated herein;

FIG. 2 illustrates a cross-sectional view of an example cooling assembly according to one or more embodiments described and illustrated herein;

FIG. 3 illustrates another cross-sectional view of the example cooling assembly of FIG. 2 according to one or more embodiments described and illustrated herein;

FIG. 4 illustrates a cross sectional view of an example droplet-forming zone of the example cooling assembly of FIG. 3 according to one or more embodiments described and illustrated herein;

FIG. 5A illustrates a top view of an example droplet-forming zone according to one or more embodiments described and illustrated herein;

FIG. 5B illustrates a top view of an example conductive evaporative substrate according to one or more embodiments described and illustrated herein;

FIG. 5C illustrates a top view of an example conductive evaporative substrate according to one or more embodiments described and illustrated herein;

FIG. 6 illustrates a partial perspective view of an example manifold and an example evaporative substrate of an example cooling assembly according to one or more embodiments described and illustrated herein;

FIG. 7A illustrates a cross sectional view of an example manifold of the example cooling assembly of FIG. 3 according to one or more embodiments described and illustrated herein; and

FIG. 7B illustrates a perspective view of an example droplet outlet of the example cooling assembly of FIG. 3 according to one or more embodiments described and illustrated herein.

### DETAILED DESCRIPTION

Embodiments of the present disclosure are directed to evaporative cooling assemblies, and more particularly, to droplet-based evaporative cooling assemblies. In droplet-based evaporative cooling assemblies, droplets are formed on an evaporative surface and then evaporated by the heat produced by a heat generating device. The evaporation of droplets removes heat from the heat-generating device. Cooling performance of a droplet-based evaporative cooler depends on many factors, such as the contact angle and dimension of droplets on the evaporative surface. However, one issue with droplet-based cooling technologies is controlling the droplet formation and evaporation to meet different cooling performances required by various heat flux situations. One specific issue with evaporative cooling technologies is controlling the boiling behaviors of droplets to minimize the formation of a vapor film at the interface between a droplet and a boiling surface, which causes the insulating effect and leads to the burnout crisis. The vapor film is formed due to the coalescence of bubbles at the boiling surface at the critical heat flux (CHF). The vapor film prevents the liquid to rewet the boiling surface, causing dryout, droplet shrinkage, and temperature fluctuation on the evaporative surface, reducing the cooling efficiency.

The cooling assemblies described herein utilize electrowetting phenomenon to adjust the wetting properties of a boiling surface according to various heat flux situations. More particularly, in embodiments, the cooling assemblies described herein include a conductive evaporative substrate having a plurality of droplet-forming zones, of which the surface wettability of an individual droplet-forming zone can be adjusted by providing an electrical field to facilitate the surface rewetting and thereby maintain the droplets, delaying the occurrence of CHF and avoiding the formation of a vapor film.

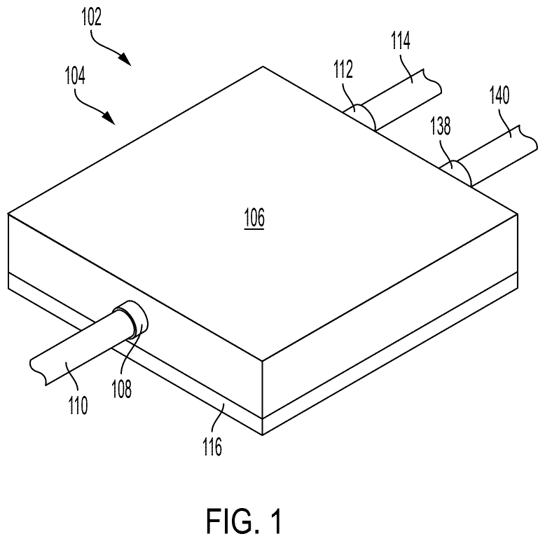

Referring now to FIG. 1, an example electronics assembly 102 is illustrated in a perspective view. The example electronics assembly 102 includes an electronic device 116 coupled to a cooling assembly 104. The cooling assembly 104 is operable to remove heat generated by the electronic device 116, or in some cases multiple electronic devices 116. The cooling assembly 104 ensures that the electronic device 116 operates below its maximum operating temperature. It is noted that embodiments disclosed herein are not limited to any electronic device 116 and, in some cases, the electronic device 116 is a heat generating component that is not an electronic device 116. Thus, the cooling assembly 104 may be used to cool any type of heat generating component.

Non-limiting example electronic devices 116 include metal-oxide-semiconductor field-effect transistors (MOSFETs), insulated-gate bipolar transistors (IGBTs), thyristors, power transistors, power diodes, and the like. As a non-limiting example, the electronic devices 116 described herein may be components of an inverter circuit of an electrified vehicle (e.g., a fully electric vehicle, a hybrid vehicle, or a plug-in hybrid vehicle) to convert direct current (DC) voltage to alternating current (AC) for powering an electric motor of the electrified vehicle. It should be understood that the electronics assemblies 102 described herein may be utilized in other applications as well.

The example cooling assembly 104 includes a housing 106 having fluid inlet port 108 for providing a cooling liquid through an inlet line 110 into an enclosure defined by the housing 106. The housing 106 also includes a liquid outlet port 112 for removing bypass liquid through a liquid outlet line 114, and a vapor outlet port 138 for removing vapor through a vapor outlet line 140. It should be understood that more than one liquid outlet port 112 and more than one vapor outlet port 138 may be provided. The fluid inlet port 108, liquid outlet port 112, and vapor outlet line 140 maybe individually disposed on a side surface, a top surface, or a bottom surface of the enclosure or other manner recognized by those skilled in the art. Further, in some embodiments the liquid outlet port 112 and the vapor outlet port 138 may be combined into a single outlet port that moves both bypass liquid and vapor from the housing 106. In some embodiments, vapor may be condensed recirculated back to the inlet line 110 through the vapor outlet line 140.

Reference will now be made in detail to the cooling assemblies, and more particularly, to embodiments that control the formation and boiling behaviors of droplets within the housing 106 to achieve improved cooling efficiency.

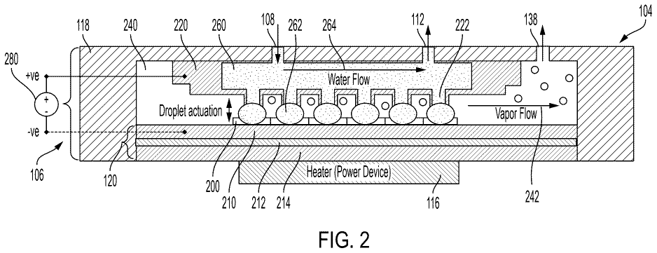

Referring now to FIG. 2, a cross-sectional view of an example cooling assembly 104 is provided. The housing 106 defines a lower housing 120 that receives heat flux from a heat generating component, such as an electronic device 116, for example. The housing 106 also defines an upper housing 118 along with side walls that form a vapor chamber 240 within the housing 106. A manifold 220 is disposed within the vapor chamber 240. The upper housing 120 may include or be fluidly coupled to the fluid inlet port 108 and the liquid outlet port 112, as shown in example cooling assembly of FIG. 2.

The lower housing 120 includes a conductive evaporative substrate 210. The lower housing 120 may further include an electric isolation layer 212 and a thermally conductive layer 214 coupled to the heat generating component, such as the electronic device 116. The conductive evaporative substrate includes a plurality of droplet-forming zones 200. Each droplet-forming zone 200 is positioned below a droplet outlet 222 defined by the manifold 220.

The manifold 220 defines a liquid channel 260 that is fluidly coupled to the liquid inlet port 108. The manifold 220 also defines a plurality of droplet outlets 222. The plurality of droplet outlets 222 are fluidly coupled to a liquid inlet port 108 through the liquid channel 260 for receiving liquid 264 and is operative to introduce droplets 262 into the vapor chamber 240. Cooling liquid 264 (e.g. water) is received from the liquid inlet port 108 and flows through the liquid channel 260. Cooling liquid 264 flowing through the liquid channel 260 enters the droplet outlets 222, such as by capillary suction, to form droplets 262 within the vapor chamber 240. The droplets 262 form between a droplet outlets 222 of the manifold 220 and a droplet-forming zone 200 disposed on the conductive evaporative substrate 210. Vapor 242 of the droplets 262 generated by receiving heat from the heat generating device, is removed from the vapor chamber through one or more vapor outlet ports 138.

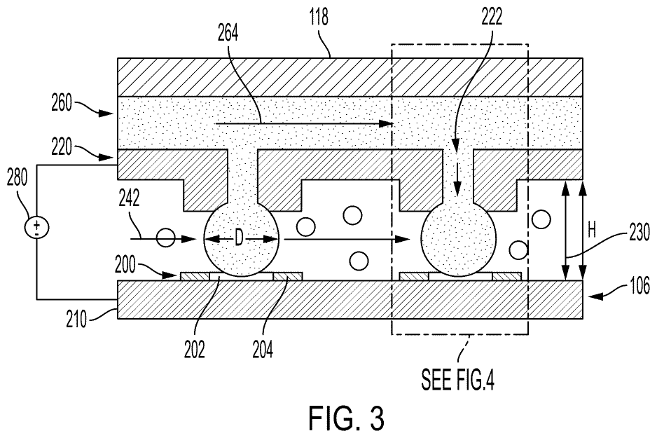

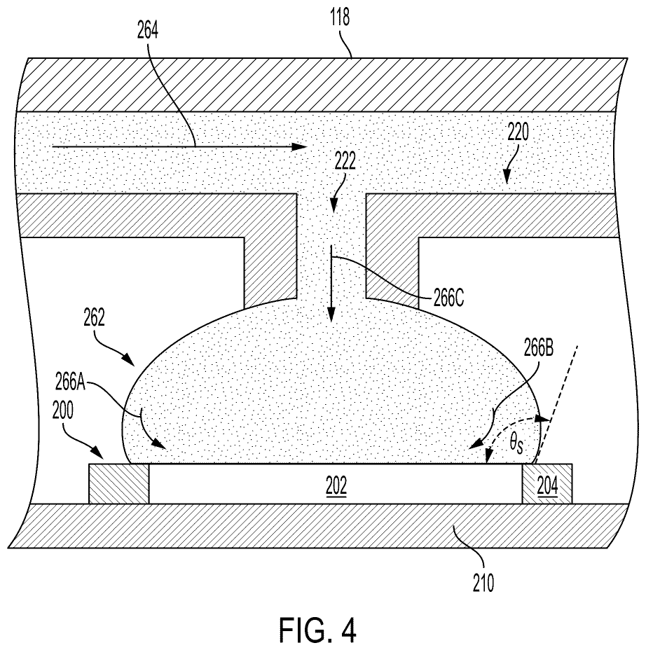

Referring to FIG. 3 and FIG. 4, the conductive evaporative substrate 210 includes a plurality of droplet-forming zones 200. As stated herein, the cooling assembly 104 operates by utilizing electrowetting phenomenon to facilitate the surface rewetting. Parameters that affect evaporative heat flux are the droplet diameter D, the contact angle θ_{S}, and the gap H. Referring to FIG. 4, during operation, droplets 262 are pinned between a droplet-forming zone 200 and a droplet outlet 222 to allow the continuous replenishment of the cooling liquid through, for example, the top of the droplet and the side of the droplet, as indicated by 266A, 266B, and 266C. For example, the heat generated by the electronic device 116 evaporates a portion of the droplets 262, which results in a gradual reduction in the diameter D. The droplet outlet 222 is operative to provide fluid to replenish the droplet 262 and therefore maintain the diameter D and contact angle θ_{S} of the droplet 262.

According to various heat flux requirements, the contact angle θ_{S} may vary. For example, if the heat flux requirement is high, a small contact angle θ_{S} would promote the spreading of droplets for faster heat removal, and therefore increasing the wettability of the boiling surface is desired. On the other hand, if the heat flux requirement is low, the wettability of the boiling surface may be reduced to balance the cooling rate. The wettability of a surface can be modified by using an electric field, which changes an effective surface tension at the edge where the droplets contacts the surface (the contact line) and therefore changes the contact angle. For example, when applying a positive voltage to a surface such as a hydrophobic surface, the hydrophobic surface may become hydrophilic, or less hydrophobic. Hydrophobic surfaces repel water, causing droplets to spread less and form contact angles ranging from 90° to 180°, resulting in larger droplet diameters. In contrast, on hydrophilic surfaces, water droplets form contact angles ranging from 10° to 90°, leading to smaller droplet diameters.

Referring once again to FIG. 3, and in embodiments, each droplet-forming zone 200 may have a boundary surface 204 and a boiling surface 202 defined by the boundary surface 204.

In some embodiments, each droplet-forming zone 200 of the plurality of droplet-forming zones 200 may have a boundary surface 204 that includes a super-hydrophobic material. As non-limiting examples, the super-hydrophobic material may include Teflon, silicones, polyurethane, polystyrene, polyethylene terephthalate, or combinations thereof. In specific embodiments, the super-hydrophobic material may include Teflon. As used herein, the term “super-hydrophobic material” or “super-hydrophobic surface” refers to a material or a surface have a water-repellent property such that a water droplet forms a contact angle greater than 150° on that material or surface.

In some embodiments, each droplet-forming zone 200 of the plurality of droplet-forming zones 200 may have a boiling surface 202 that includes a super-hydrophilic material. As non-limiting examples, the super-hydrophilic material may include TiO₂, ZnO, WO₃, or combinations thereof. As used herein, the term “super-hydrophilic material” or “super-hydrophilic surface” refers to a material or a surface have a high affinity for water such that a water droplet forms a contact angle less than 10° on that material or surface.

In some embodiments, each droplet-forming zone 200 of the plurality of droplet-forming zones 200 may have a boundary surface 204 that includes a super-hydrophobic material disclosed herein and a boiling surface 202 that include a super-hydrophilic material disclosed herein.

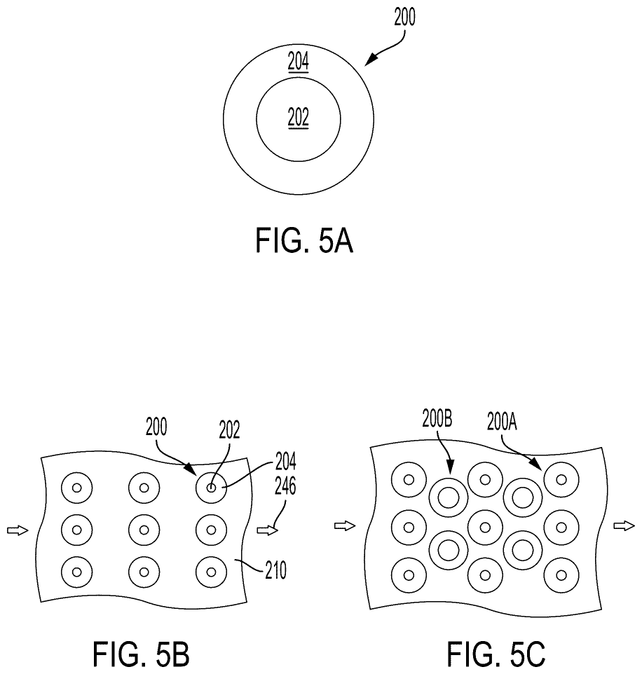

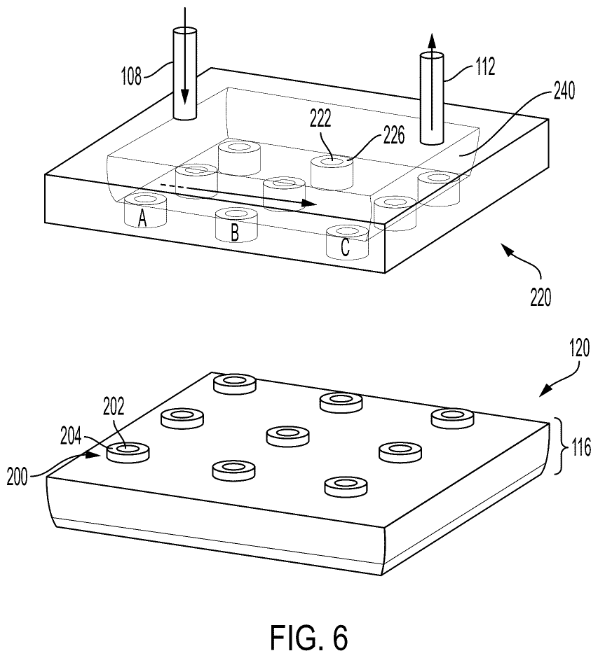

The dimension and shape of the droplet-forming zone 200 may be tailored according to various heat flux requirements. Referring to FIG. 5A, for non-limiting example, the droplet-forming zone 200 may have a circular shape, a rectangular shape, or a free-form shape. In some embodiments, the boiling surface 202 may have a dimension (a diameter, a length, or a width) from 1 cm×1 cm to 10 cm×10 cm, such as from 1 cm×1 cm to 8 cm×8 cm, from 1 cm×1 cm to 6 cm×6 cm, from 1 cm×1 cm to 3 cm×3 cm, from 3 cm×3 cm to 10 cm×10 cm, from 3 cm×3 cm to 8 cm×8 cm, from 3 cm×3 cm to 6 cm×6 cm, from 6 cm×6 cm to 10 cm×10 cm, from 6 cm×6 cm to 8 cm×8 cm, or from 8 cm×8 cm to 10 cm×10 cm. For example, the boiling surface 202 may be have a circular shape with a diameter from 10 mm to 100 mm, such as from 10 mm to 80 mm, from 10 mm to 70 mm, from 10 mm to 60 mm, from 10 mm to 50 mm, from 10 mm to 25 mm, from 10 mm to 15 mm, from 15 mm to 100 mm, from 15 mm to 80 mm, from 15 mm to 70 mm, from 15 mm to 60 mm, from 15 mm to 50 mm, from 15 mm to 25 mm, from 25 mm to 100 mm, from 25 mm to 80 mm, from 25 mm to 70 mm, from 25 mm to 60 mm, from 25 mm to 50 mm, from 50 mm to 100 mm, from 50 mm to 80 mm, from 50 mm to 70 mm, from 50 mm to 60 mm, from 60 mm to 100 mm, from 60 mm to 80 mm, from 60 mm to 70 mm, from 70 mm to 100 mm, from 70 mm to 80 mm, or from 80 mm to 100 mm.

In some embodiments, the boundary surface 204 may have a width from 1 mm to 10 mm, from 1 mm to 7.5 mm, from 1 mm to 5 mm from 1 mm to 2.5 mm, from 2 mm to 10 mm, from 2 mm to 9 mm, from 2 mm to 7 mm, from 2 mm to 5 mm, from 2 mm to 3 mm, from 4 mm to 10 mm, from 4 mm to 8 mm, from 4 mm to 6 mm, from 5 mm to 10 mm, from 5 mm to 7.5 mm, from 7 mm to 10 mm, from 7 mm to 8.5 mm, from 8 mm to 10 mm, from 8 mm to 9 mm, or from 9 mm to 10 mm, measured by the smallest distance from the outer edge of the boundary surface 204 to the outer edge of the boiling surface 202.

The droplet-forming zones 200 may be disposed on the conductive evaporative substrate 210 in a spatial arrangement according to various heat flux requirements. Also, the droplet-forming zones 200 disposed on the conductive evaporative substrate 210 need not have a uniform size or a uniform shape.

For example, referring to FIG. 5B, the conductive evaporative substrate 210 may have an array of the droplet-forming zones 200 described herein, and the droplet-forming zones 200 have a uniform size and a uniform shape. For example, referring to FIG. 5C, the conductive evaporative substrate 210 may have a closely-packed array of the droplet-forming zones 200A and 200B described herein, and the droplet-forming zones 200A and 200B have different sizes.

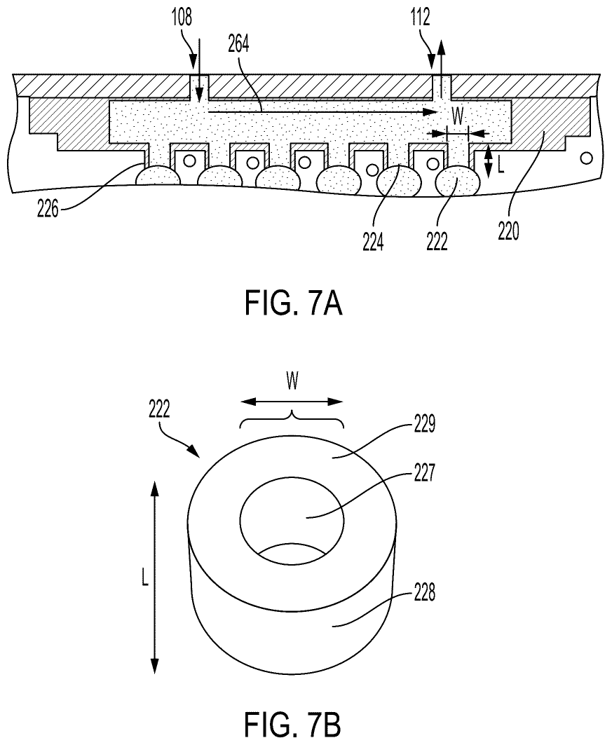

Based on the spatial arrangement of the droplet-forming zones 200 on the conductive evaporative substrate 210, the droplet outlets 222 defined by the manifold 220 will have a corresponding spatial arrangement to ensure that each droplet-forming zone 200 is aligned with a droplet outlet 222, as shown in FIG. 7. The manifold 220 and droplet outlets 222 will be subsequently described.

As mentioned herein, the surface wettability of the boundary surface 204, the boiling surface 202, or both may be modified by an actuation voltage provided from a voltage supply 280 connected to the cooling assembly as shown in FIG. 2. Changing the surface wettability can improve the heat removal. As an example, a 68 μL water drop on a hydrophilic surface can remove 80 mW of power from a heated surface, which is twice as much as compared to a hydrophobic surface. Thus, with a 100×100 array of cooling liquid droplets a total power about 800 W can be removed.

Furthermore, by adjusting surface wettability to facilitate surface rewetting according to embodiments disclosed herein, the formation of vapor film is delayed due to increased CHF and hydrodynamic instability. As described herein, and in embodiments, the CHF is increased from 5% to 15%, such as from 5% to 12%, from 5% to 10%, from 5% to 7.5%, from 7.5% to 15%, from 7.5% to 12%, from 7.5% to 10%, from 10% to 15%, from 10% to 12%, from 12% to 15%, when the actuation voltage is applied.

Referring back to FIG. 2, the conductive evaporative substrate 210 and the manifold 220 are connected to a voltage supply 280. The voltage supply 280 is configured to provide an actuation voltage between the conductive evaporative substrate 210 and the manifold 220. The actuation voltage is operable to adjust a surface wettability of each droplet-forming zone 200 of the plurality of droplet-forming zones 200 and a contact angle of a droplet 262 of the cooling liquid 264 in each droplet-forming zone 200 of the plurality of droplet-forming zones 200.

For example, and in embodiments, the actuation voltage may be operable to adjust the surface wettability of a boundary surface 204. In other embodiments, the actuation voltage may be operable to adjust the surface wettability of a boiling surface 202. In specific embodiments, the actuation voltage may be operable to adjust the surface wettability of both the boundary surface 204 and the boiling surface 202. For specific example, and in specific embodiments, the actuation voltage may be operable to adjust the surface wettability of the boundary surface 204 and the boiling surface 202 such that the contact angle of the droplet 262 on a droplet-forming zone 200 is from 10° to 90°, such as from 10° to 70°, from 10° to 50°, from 10° to 45°, from 10° to 30°, from 10° to 15°, from 15° to 90°, from 15° to 70°, from 15° to 60°, from 15° to 50°, from 15° to 45°, from 15° to 30°, from 30° to 90°, from 30° to 70°, from 30° to 60°, from 30° to 50°, from 30° to 45°, from 45° to 90°, from 45° to 70°, from 45° to 60°, from 60° to 90°, from 60° to 70°, from 70° to 90°, from 70° to 80°, or from 80° to 90° during operation.

As discussed herein, the wettability of a surface is changed according to the value and also sign of the applied voltage. In some embodiments, the voltage supply may provide alternating current such that the actuation voltage may alternates between positive and negative values. Alternating the electric field may oscillate the surface tension at the liquid-vapor interface, destabilizing the liquid-vapor interface and causing a vapor film to collapse.

In other embodiments, the voltage supply may provide direct current such that the actuation voltage may be a positive voltage or a negative voltage. In specific embodiments, the actuation voltage may be a positive voltage. The value of actuation voltage may be from 100 V to 1000 V, such as from 100 V to 900 V, from 100 V to 800 V, from 100 V to 700 V, from 100 V to 600 V, from 100 V to 500 V, from 100 V to 400 V, from 100 V to 300 V, from 100 V to 200 V, from 200 V to 1000 V, from 200 V to 900 V, from 200 V to 800 V, from 200 V to 700 V, from 200 V to 600 V, from 200 V to 500 V, from 200 V to 400 V, from 200 V to 300 V, from 300 V to 1000 V, from 300 V to 900 V, from 300 V to 800 V, from 300 V to 700 V, from 300 V to 600 V, from 300 V to 500 V, from 300 V to 400 V, from 400 V to 1000 V, from 400 V to 900 V, from 400 V to 800 V, from 400 V to 700 V, from 400 V to 600 V, from 400 V to 500 V, from 500 V to 1000 V, from 500 V to 900 V, from 500 V to 800 V, from 500 V to 700 V, from 500 V to 600 V, from 600 V to 1000 V, from 600 V to 900 V, from 600 V to 800 V, from 600 V to 700 V, from 700 V to 1000 V, from 700 V to 900 V, from 700 V to 800 V, from 800 V to 1000 V, from 800 V to 900 V, or from 900 V to 1000 V.

It is contemplated that the cooling assembly 104 may further include a programmable controller configured to provide static control or dynamic control of the voltage supply 280 and the actuation voltage provided from the voltage supply 280.

For example, the actuation voltage may be operable to maintain the contact angle of the droplet 262 of the cooling liquid 264 in each droplet-forming zone 200 of the plurality of droplet-forming zones 200 during operations. In some embodiments, the actuation voltage may be operable to maintain the contact angle of the droplet 262 such that a variation of the contact angle less than 30°, such as less than 20°, less than 10°, less than 5°, from 5° to 30°, from 5° to 20°, from 5° to 10°, from 10° to 30°, from 10° to 20°, or from 20° to 30° during operation.

For example, and in embodiments, the actuation voltage may be operable to maintain a variation in surface temperature of a boiling surface 202 less than 5° C., such as less than 2° C., or from 2° C. to 5° C. during operations. For example, and in embodiments, the actuation voltage may be operable to maintain an average variation in surface temperature of the conductive evaporative substrate 210 less than 5° C., such as less than 2° C., or from 2° C. to 5° C. during operations.

As discussed herein, in addition to the contact angle θ_{S}, parameters that affect evaporative heat flux include the droplet diameter D and the gap H.

Referring back to FIG. 3, a distance or a gap H is present between the manifold 220 and the conductive evaporative substrate 210. The gap H dictates how fast the droplets 262 evaporate. The smaller the gap, the higher the evaporative heat flux. During the evaporation process the droplets 262 exert capillary pressure or suction on the top surface of the manifold 220. Depending on the gap H (e.g., 0.3 mm-1 mm), a suction pressure within a range of 50 Pa to 100 Pa, including endpoints, is generated. This suction pressure is utilized to pump the cooling liquid 264 into the droplets 262 for replenishment to maintain a constant contact angle and continue the evaporation process to achieve higher heat fluxes.

In embodiments, the gap H may be maintained at a constant distance from 0.3 mm to 1 mm such that the droplet size is varied using the actuation voltage described herein. The flexures 230 may be made of any type of suitable material recognized by those of ordinary skill in the art.

In other embodiments, the gap H may be adjusted according to various heat flux requirements. In some embodiments, the gap H may be adjusted to accommodate for non-uniform vapor generation and large droplet volumes depending on the application and desired performance. In some embodiments, the gap H may be reduced to increase the evaporative flux.

Flexures 230 that are conventionally available or yet-to-be-developed may be provided to adjust the gap H to continuously tune the performance of the cooling assembly. For example, one or more flexures 230 may be provided between the lower housing 120 and the upper housing 106 (or manifold 220 in some embodiments) that are operable to be controlled to change length. The changing of the length of the flexures 230 adjusts the gap H on demand. Therefore, the performance of the cooling assembly 104 can be tuned in real time to meet cooling demands.

The flexures 230 may be made of any type of suitable material. As a non-limiting example, the flexure 230 may be fabricated from a memory-shape alloy that changes length due to stimuli, such as heat, voltage or light. The material of the flexure 230 may be tuned to adjust its length in response to heat to continuously tune the gap H to provide optimal evaporative flux. The flexures 230 may be used in both the active and passive cooling assembly embodiments.

The droplet diameter D can also be tuned to the desired power dissipation of the cooling assembly 104. Particularly, the droplet diameter is tuned such that liquid is supplied to continuously replenish evaporated droplets 262. It is noted that the droplet diameter D depends on the dimension and surface wettability of a droplet-forming zone 200, the actuation voltage, as well as the distance (H) between a droplet-forming zone 200 and a droplet outlet 222.

For example, and in some embodiments, the actuation voltage described herein may be operable to adjust a surface wettability of the boundary surface 204, the boiling surface 202, or both such that, during operation, the diameter of the droplet 262 is from 1 mm to 10 mm, such as from 1 mm to 7.5 mm, from 1 mm to 5 mm, from 1 mm to 4 mm, from 1 mm to 3 mm, from 1 mm to 2 mm, from 2 mm to 10 mm, from 2 mm to 7.5 mm, from 2 mm to 5 mm, from 2 mm to 4 mm, from 2 mm to 3 mm, from 3 mm to 10 mm, from 3 mm to 7.5 mm, from 3 mm to 5 mm, from 3 mm to 4 mm, from 4 mm to 10 mm, from 4 mm to 7.5 mm, from 4 mm to 5 mm, from 5 mm to 10 mm, from 5 mm to 7.5 mm, or from 7.5 mm to 10 mm.

In specific embodiments, the actuation voltage may be operable to adjust a surface wettability of the boundary surface 204, the boiling surface 202, or both such that, during operation, the contact angle of the droplet 262 is from 10° to 90° as disclosed and described herein and the diameter of the droplet 262 is from 1 mm to 10 mm as disclosed and described herein.

As noted herein, the cooling assembly 104 disclosed here may include both the active and passive cooling assembly embodiments. Thus, in some embodiments, the actuation voltage may be operable to maintain the diameter D of the droplet 262 such that, during operation, a variation of the diameter D is from 0.1 mm to 4 mm, such as from 0.5 mm to 4 mm, from 1 mm to 4 mm, from 1.5 mm to 4 mm, from 2 mm to 4 mm, from 2.5 mm to 4 mm, from 3 mm to 4 mm, from 3.5 mm to 4 mm, from 0.1 mm to 3.5 mm, from 0.5 mm to 3.5 mm, from 1 mm to 3.5 mm, from 1.5 to 3.5 mm, from 2 mm to 3.5 mm, from 3 mm to 3.5 mm, from 0.1 mm to 3 mm, from 0.5 mm to 3 mm, from 1 mm to 3 mm, from 1.5 mm to 3 mm, from 2 mm to 3 mm, from 2.5 mm to 3 mm, from 0.1 mm to 2.5 mm, from 0.5 mm to 2.5 mm, from 1 mm to 2.5 mm, from 1.5 mm to 2.5 mm, from 2 mm to 2.5 mm, from 0.1 mm to 2 mm, from 0.5 mm to 2 mm, from 1 mm to 2 mm, from 1.5 mm to 2 mm, from 0.1 mm to 1.5 mm, from 0.5 mm to 1.5 mm, from 1 mm to 1.5 mm, from 0.1 mm to 1 mm, from 0.5 mm to 1 mm, or from 0.1 mm to 0.5 mm. In some embodiments, the actuation voltage may be operable to maintain, during operation, a variation of the contact angle that is less than 30° as disclosed and described herein and a variation of the diameter D that is from 0.1 mm to 4 mm as disclosed and described herein.

Reference will now be made in detail to the manifold 220, the droplet outlets 222, and the vapor chamber 240.

Still referring to FIG. 2, the example cooling assembly 104 is a top-feed structure whereby cooling liquid 264 is introduced through the manifold 220 and a plurality of droplet outlets 222 defined by the manifold into the vapor chamber 240 to form droplets 262. The manifold 220 also defines a liquid channel 260 that is fluidly coupled to the liquid inlet port 108.

Referring now to FIG. 7A, the manifold 220 has a plurality of droplet outlets 222. As mentioned herein, the manifold 220 is connected to a voltage supply 280. The manifold may include a conductive material or a conductive coating. Therefore, the surface wettability of the manifold 220 and droplet outlets 222 may also be adjusted by utilizing electrowetting phenomenon.

Referring to FIG. 7B, for example and in embodiments, the channel wall 226 of a droplet outlet 222 may include an inner surface 227, an outer surface 228, and a droplet surface 229. The inner surface 227 may include a hydrophobic material or a hydrophobic coating to reduce the retention of the cooling liquid 264 and thereby increase the flow of the cooling liquid 264. In some embodiments, the inner surface 227 may include a super-hydrophobic material or a super-hydrophobic coating described herein, and the surface wettability of the inner surface 227, and consequently the flow of the cooling liquid 264, may be adjusted according to the actuation voltage as described herein.

Each droplet outlet 222 include a droplet channel 224 defined by a channel wall 226. The droplet channel may have a diameter W from 0.5 mm to 1 mm, such as from 0.5 mm to 0.9 mm, from 0.5 mm to 0.8 mm, from 0.5 mm to 0.7 mm, from 0.5 mm to 0.6 mm, from 0.6 mm to 1 mm, from 0.6 mm to 0.9 mm, from 0.6 mm to 0.8 mm, from 0.6 mm to 0.7 mm, from 0.7 mm to 1 mm, from 0.7 mm to 0.9 mm, from 0.7 mm to 0.8 mm, from 0.8 mm to 1 mm, from 0.8 mm to 0.9 mm, or from 0.9 mm to 1 mm. The droplet channel may have a length L from 1 mm to 10 mm, such as from 1 mm to 8.5 mm, from 1 mm to 7 mm, from 1 mm to 5.5 mm, from 1 mm to 4 mm, from 1 mm to 2.5 mm, from 2.5 mm to 10 mm, from 2.5 mm to 8.5 mm, from 2.5 mm to 7 mm, from 2.5 mm to 5.5 mm, from 2.5 mm to 4 mm, from 4 mm to 10 mm, from 4 mm to 8.5 mm, from 4 mm to 7 mm, from 4 mm to 5.5 mm, from 5.5 mm to 10 mm, from 5.5 mm to 8.5 mm, from 5.5 mm to 7 mm, from 7 mm to 10 mm, from 7 mm to 8.5 mm, or from 8.5 mm to 10 mm. As mentioned herein, the droplet outlets 222 are arranged in corresponding to the arrangement of the droplet-forming zones positioned below the droplet outlets. It is noted that the dimension of the droplet outlets 222, such as the diameter W of the droplet channel 224 is not required to be identical to the diameter of the boiling surface 202 or the overall dimension of the droplet-forming zone 200.

To conclude, according to embodiments disclosed herein, adjusting surface wettability could facilitate surface rewetting in a droplet-based cooler system, increase the wetted area fraction, and delay the CHF and the formation of vapor film.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Further, it will be apparent that modifications and variations are possible without departing from the scope of the present disclosure, including, but not limited to, embodiments defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present disclosure, it is noted that this term is introduced in the claims as an open-ended transitional phrase that is used to introduce a recitation of a series of characteristics of the structure and should be interpreted in like manner as the more commonly used open-ended preamble term “comprising.”

It is noted that the singular forms “a,” “an” and “the” include plural referents unless the context clearly dictates otherwise. Thus, for example, reference to “a” component includes aspects having two or more such components, unless the context clearly indicates otherwise.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

All numerical ranges' herein expressed in the format “from X to Y” are to be interpreted as including the endpoints X and Y and all numbers between the endpoints.

What is claimed is:

1. A cooling assembly, comprising:
a plurality of droplet-forming zones on a conductive evaporative substrate;
a manifold comprising a plurality of droplet outlets fluidly coupled to a liquid inlet port for receiving cooling liquid;
a chamber positioned between the conductive evaporative substrate and the manifold and operable to transport vapor from the plurality of droplet-forming zones to a vapor outlet port; and
a voltage supply configured to provide an actuation voltage between the conductive evaporative substrate and the manifold;
wherein:
the actuation voltage is operable to adjust a surface wettability of each droplet-forming zone of the plurality of droplet-forming zones and a contact angle of a droplet of the cooling liquid in each droplet-forming zone of the plurality of droplet-forming zones.

2. The cooling assembly of claim 1, wherein each droplet-forming zone of the plurality of droplet-forming zones comprises a boundary surface and a boiling surface defined by the boundary surface, wherein the boundary surface comprises a super-hydrophobic material.

3. The cooling assembly of claim 2, wherein the super-hydrophobic material comprises Teflon.

4. The cooling assembly of claim 2, wherein the boiling surface comprises a super-hydrophilic material.

5. The cooling assembly of claim 2, wherein the boiling surface comprises a super-hydrophilic material comprising TiO₂.

6. The cooling assembly of claim 2, wherein the actuation voltage is operable to adjust a surface wettability of the boundary surface, the boiling surface, or both of an individual droplet-forming zone of the plurality of droplet-forming zones during operations.

7. The cooling assembly of claim 2, wherein the actuation voltage is operable to maintain the contact angle of a droplet in an individual droplet-forming zone of the plurality of droplet-forming zones during operations.

8. The cooling assembly of claim 2, wherein the actuation voltage is operable to maintain a variation in surface temperature of a boiling surface of an individual droplet-forming zone less than or equal to 5° C. during operations.

9. The cooling assembly of claim 1, wherein the actuation voltage is positive.

10. The cooling assembly of claim 1, wherein the actuation voltage is from 100 V to 1000 V.

11. The cooling assembly of claim 1, wherein each droplet-forming zone of the plurality of the droplet-forming zones is configured to receive the cooling liquid provided by an individual droplet outlet of the plurality of droplet outlets and form a droplet of the cooling liquid.

12. The cooling assembly of claim 11, wherein each droplet-forming zone of the plurality of the droplet-forming zones is positioned at a distance (H) from 0.3 mm to 1 mm below an individual droplet outlet of the plurality of droplet outlets.

13. The cooling assembly of claim 1, wherein the cooling liquid is water.

14. The cooling assembly of claim 1, further comprising a programmable controller configured to provide a static control or a dynamic control to the voltage supply and the actuation voltage provided from the voltage supply during operations.

15. An electronic assembly comprising a cooling assembly of claim 1.

16. A method of cooling a heat generating component, comprising:
providing an actuation voltage and cooling liquid to a cooling assembly configured to receive heat flux from the heat generating component, wherein the cooling assembly comprises:
a plurality of droplet-forming zones on a conductive evaporative substrate;
a manifold comprising a plurality of droplet outlets fluidly coupled to a liquid inlet port for receiving the cooling liquid;
a voltage supply configured to provide the actuation voltage between the conductive evaporative substrate and the manifold, and
a chamber positioned between the conductive evaporative substrate and the manifold and operable to transport vapor from the plurality of droplet-forming zones to a vapor outlet port;
wherein:
the actuation voltage is operable to adjust a surface wettability of each droplet-forming zone of the plurality of droplet-forming zones and a contact angle of a droplet of the cooling liquid in each droplet-forming zone of the plurality of droplet-forming zones;
receiving the cooling liquid from the plurality of droplet outlets to form a droplet on each droplet-forming zone of the plurality of droplet-forming zones;
receiving heat flux from the heat generating component; and
transporting vapor from the plurality of droplet-forming zones to the vapor outlet port and thereby removing heat flux from the heat generating component.

17. The method of claim 16, wherein each droplet-forming zone of the plurality of droplet-forming zones comprises a boundary surface and a boiling surface defined by the boundary surface, wherein the boundary surface comprises a super-hydrophobic material.

18. The method of claim 17, further comprising:
adjusting the actuation voltage to adjust a surface wettability of the boundary surface, the boiling surface, or both of an individual droplet-forming zone of the plurality of droplet-forming zones during operations; or
adjusting the actuation voltage to maintain the contact angle of a droplet in an individual droplet-forming zone of the plurality of droplet-forming zones during operations; or
adjusting the actuation voltage to maintain a variation in surface temperature of the boiling surface of an individual droplet-forming zone less than 5° C. during operations; or
combinations thereof.

19. The method of claim 16, wherein the actuation voltage is positive.

20. The method of claim 16, wherein the cooling assembly further comprises a programmable controller, further comprising:
configuring the programmable controller to adjust the actuation voltage.
